(19) United States
(12) Patent Application Publication
(10) Pub. No.: US 2009/0086996 A1
(43) Pub. Date: Apr. 2, 2009

(54) SYSTEM AND METHOD FOR PROCESSING AUDIO SIGNAL

(76) Inventors: Anthony Bongiovi, Port St. Lucie, FL (US); Phillip Fuller, New York, NY (US)

Correspondence Address: DON J. PELTO;Sheppard, Mullin, Richter & Hampton LLP, 1300 I STREET, NW, 11TH FLOOR EAST, WASHINGTON, DC, 20005, US

(21) Appl. No.: 12/332,872

(22) Filed: Dec. 11, 2008

Related U.S. Application Data
(63) Continuation-in-part of application No. 11/764,446, filed on Jun. 18, 2007.

(51) Int. Cl. H03G 7/00

(52) U.S. Cl. 381/106

(57) ABSTRACT

The present invention provides for methods and systems for digitally processing an audio signal. Specifically, the present invention provides for a speaker system that is configured to digitally process an audio signal in a manner such that studio-quality sound that can be reproduced.

### CROSS-REFERENCE TO RELATED APPLICATIONS

The present application is a continuation-in-part of and claims priority under 35 U.S.C. § 120 to U.S. patent application Ser. No. 11/764,446 filed Jun. 18, 2007, which claims priority to U.S. patent application Ser. No. 10/914,234 filed Aug. 10, 2004, now U.S. Pat. No. 7,254,243, each of which is expressly incorporated fully herein.

### TECHNICAL FIELD

This invention relates to apparatus for processing an audio signal and, in particular, to apparatus which is particularly useful for presenting enhanced quality sound in a high noise environment.

### DESCRIPTION OF THE RELATED ART

Historically studio-quality sound, which can best be described as the full reproduction of the complete range of audio frequencies that are utilized during the studio recording process, has only been able to be achieved, appropriately, in audio recording studios. Studio-quality sound is characterized by the level of clarity and brightness which is attained only when the upper-mid frequency ranges are effectively manipulated and reproduced. Achieving studio-quality sound in high-noise environments, such as moving vehicles, remains particularly challenging. For example, the bass response of a system in such an environment is generally inadequate. While the bass response may be boosted with an equalizer to compensate for this inadequacy this approach typically causes a muffled treble response, thus diminishing the sound quality. In addition to a muffled treble, bass boosting may undesirably increase the dynamic range of the sound presentation.

Typically, the dynamic range of sound in motion pictures can be created and mixed in an environment the size of a movie theater. Thus the quality of playback of motion picture audio in a small environment, such as a home entertainment area or an automobile, is marginal. In a small environment audio standing waves often develop, producing an annoying acoustical signal at the frequency of the standing wave. Compensation for such specific standing waves in a given small environment would produce a higher quality audio presentation.

Additionally, in a noisy environment, there is very little audio range between the volume floor set by the noise (typically around 80 dB in moving vehicles) and the volume ceiling set by the physiology of the ear (typically around 110 dB). Increasing the dynamic range of sound presented in a noisy environment may be aesthetically undesirable because the sound level may approach the ear's physiological volume ceiling, resulting in an unpleasant, annoying, or even painful experience.

Typical consumer sound transducers, such as commercial speakers, are acoustically efficient between approximately 600 and 1,000 cycles. To compensate for the inefficient performance of such transducers outside this range, conventional systems often employ a variety of special speakers and amplifiers that can be quite expensive. For example, attempts have been made to reproduce studio-quality sound outside of the recording studio, those attempts have come at tremendous expense (usually resulting from advanced speaker design, costly hardware, and increased power amplification) and have achieved only mixed results.

Further, the design of audio systems for vehicles involves the consideration of many different factors. The audio system designer selects the position and number of speakers in the vehicle. The desired frequency response of each speaker must also be determined. For example, the desired frequency response of a speaker that is located on the instrument panel may be different than the desired frequency response of a speaker that is located on the lower portion of the rear door panel.

The audio system designer must also consider how equipment variations impact the audio system. For example, an audio system in a convertible may not sound as good as the same audio system in the same model vehicle that is a hard top. The audio system options for the vehicle may also van significantly. One audio option for the vehicle may include a basic 4-speaker system with 40 watts amplification per channel while another audio option may include a 12-speaker system with 200 watts amplification per channel. The audio system designer must consider all of these configurations when designing the audio system for the vehicle. For these reasons, the design of audio systems is time consuming and costly. The audio system designers must also have a relatively extensive background in signal processing and equalization.

Given those considerations, in order to approach or achieve studio-quality sound in a vehicle historically one would have to provide, for example, upgrades to the Factory-installed speakers, and/or the addition of additional components, including woofers, sub-woofers, amplifiers, etc. As such, there is a need for systems and methods that can reproduce studio-quality sound in a vehicle without requiring such upgrades and/or additions.

### BRIEF SUMMARY OF EMBODIMENTS OF THE INVENTION

The present invention provides a system and method for digitally processing an audio signal in a manner such that studio-quality sound that can be reproduced across essentially the entire spectrum of audio devices. In one implementation, the methods of the present invention comprise: receiving an audio signal; filtering the audio signal to obtain a generally flat power spectral density across a plurality of frequencies of the audio signal; compressing the filtered audio signal to increase a dynamic range of the filtered audio signal; filtering the compressed audio signal to generate an audio signal with a variable energy spectral density; and outputting the audio signal.

In one embodiment, the filtering procedure comprises filtering the audio signal with a high and a low shelving filters. Each filter used in the filtering procedure may have a cutoff frequency of approximately 1000 Hz. The filtering procedure can be configured to reduce or increase a power of a low audible bass portion of the audio signal up to 12 dB. In one specific embodiment, the low audible bass portion is reduced by approximately 10 dB and high audible treble portion is increased by approximately 8 dB. Additionally, the filtering procedure may further filter the audio signal with a set of “mirror image” filter. The mirror image filter may comprise a high and a low shelving filters that are chosen so that they have equal and opposite effects of the preceding filtering procedure.

In yet another embodiment, the method further comprises conditioning the filtered audio signal having the variable energy spectral density with an equalizer. In one embodiment the graphic equalizer may comprise one or more second order filters. In a specific embodiment, the graphic equalizer may comprise eleven cascading second order filters. Each filter can be a bell filter. The first of the eleven filers can have a center frequency of 30 Hz and the eleventh filter of the eleven filters can have a center frequency of 16000 Hz. The second to tenth filters can be centered at approximately one octave intervals from each other.

In still another embodiment, the method further comprises compressing the conditioned audio signal with a second compressor. In still another embodiment, the method includes a procedure of amplifying a gain of the compressed signal prior to outputting the signal.

In accordance with another embodiment of the present invention, an apparatus for processing an audio signal is provided. The apparatus may comprise: a first set of filters configured to filter an audio signal to obtain a generally flat power spectral density across a plurality of frequencies of the audio signal; a gain controller configured to increase a dynamic range of the filtered audio signal; and a second set of filters configured to generate an audio signal with a variable energy spectral density.

The first set of filters may comprise a high and a low shelving filters. Each filter may have a cutoff frequency of approximately 1000 Hz. The first set of filters can be configured to reduce a power of a low audible bass portion of the audio signal by approximately 10 dB. The first set of filters can also be configured to reduce a power of a high audible treble portion of the audio signal by approximately 8 dB.

In yet another embodiment, the apparatus may additionally comprise an equalizer for conditioning the audio signal from the second set of filters and a graphic equalizer. In one embodiment, the graphic equalizer may comprise one or more second order filters. In a specific embodiment, the graphic equalizer may have eleven cascading second order filters. Each filter can be a bell filter.

In still another embodiment, the audio processing apparatus may additionally comprise a compressor configured to compress the conditioned audio signal. The apparatus may also comprise an amplifier configured to amplify a gain of the compressed signal prior to outputting the signal.

Other features and aspects of the invention will become apparent from the following detailed description, taken in conjunction with the accompanying drawings, which illustrate, by way of example, the features in accordance with embodiments if the invention. The summary is not intended to limit the scope of the invention which is defined solely by the embodiments attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

FIGS. 1A-C illustrate example environments in which a method for processing an audio signal according to embodiments of the present invention can be implemented.

FIG. 2 illustrates a flow chart of a signal processing method according to one embodiment of the present invention.

FIG. 3 illustrates a flow chart of a signal processing method according to one embodiment of the present invention.

FIG. 4 illustrates a flow chart of a signal processing method according to one embodiment of the present invention.

FIG. 5 illustrates an exemplary computer system in which the signal processing method according to one embodiment can be implemented.

The figures are not intended to be exhaustive or to limit the invention to the precise form disclosed. It should be understood that the invention can be practiced with modification and alteration, and that the invention be limited only by the embodiments and the equivalents thereof.

### DETAILED DESCRIPTION OF THE EMBODIMENTS OF THE INVENTION

The present invention is directed toward systems and methods for digitally processing an audio signal in a manner such that studio-quality sound can be reproduced across the entire spectrum of auto devices.

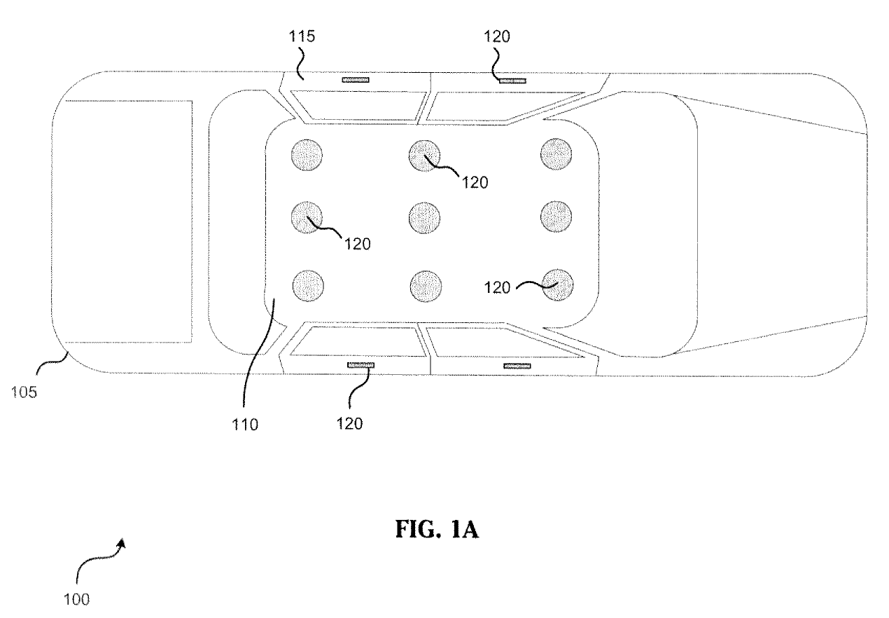

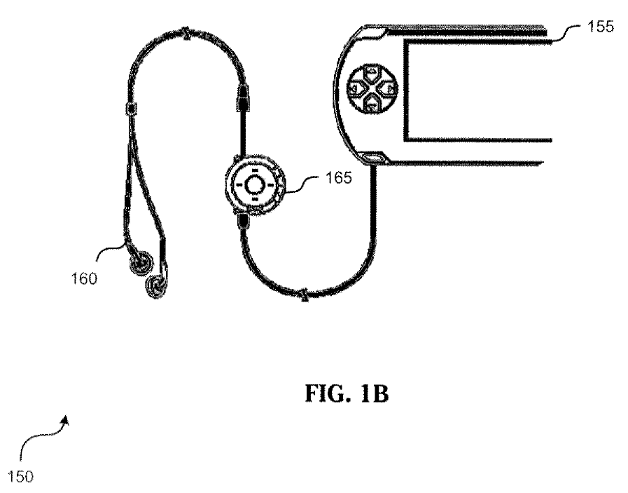

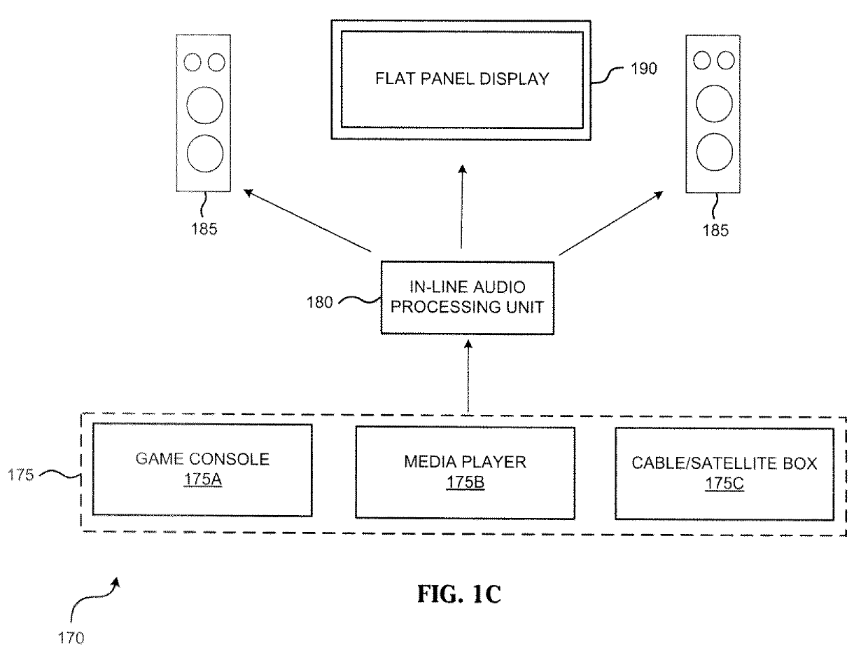

Before describing the invention in detail, it is useful to describe a few example environments with which the invention can be implemented. One such example is that of a passenger cabin of a vehicle. FIG. 1A shows an exemplary automotive environment where a panel-speaker system 10, according to an embodiment of the present invention, can be implemented. As shown in FIG. 1A speaker system 100 is located in a vehicle 105. Speaker system 160 includes an array of transducers 120 on a roof panel 110 and door panel 115 of vehicle 105. Although not shown, transducers 120 may be positioned in other areas such as, but not limited to, kicker panel, trunk, seat back, dashboard, lift gate, firewall, and hood of vehicle 105, etc. In one embodiment, item 120 can also be a conventional speaker a speaker having a basket and a cone. Alternatively, system 100 includes a combination of transducers and conventional speakers.

Transducer 120 may comprise an audio drive motor configured to convert electrical signals into mechanical energy or vibrations. The mechanical energy or vibrations produced by transducer 120 are transferred to roof panel 110 which in turn transmits the mechanical energy to a passenger cabin as sound. Transducer 120 may be generally flat and has no protruded part like a cone or a basket of a conventional speaker. Thus transducer 120 is relatively safe for use in various consumer environments and small spaces such as automobiles, boats, airplanes, trains, and furniture. Panel 110 may be comprised of various materials such as fiberglass, wood, plastic, stiff upholstery, and/or other suitable material that cm be excited to generate sound, or a combination of materials. In one specific embodiment, panel 110 may be comprised of fiberglass.

Panel 110 may be comprised of a single layer of material or can have multiple layers of one or more materials. In one specific embodiment, panel 110 may comprise three layers with the middle layer being sandwiched by two outer layers of the same materials. The middle layer may be comprised of a foam material or other suitable insulating or porous material. The two outer layers may be comprised from fiberglass.

In another embodiment, system 100 may also be associated with any other pane or surface that can be excited to generate sound such as, but not limited to panels and specifically the headliners in the interiors of vehicles, such as airplanes, helicopters, trains, and boats, for example. This also includes other interior or exterior surfaces of, for example vehicles, buildings or other objects, and specifically panels, including walls, ceiling, floors and children's toys, helmets, and furniture (such as tables, chairs sofas, and headboards for beds). In yet another embodiment, the panel may comprise, or be separately attached to, one or more of the group consisting of interior door moldings (front and/or rear) package tray pillar/column/support structures, seat backs, dashboard, lift gates (rear doors), trunk, firewall (front or rear), and interior kick panels of a vehicle ad specifically a motor vehicle such as an automobile.

FIG. 1B shows a consumer device, with an audio output, in which the signal processing method or apparatus can be implemented according to one embodiment of the present invention. Referring now to FIG. 1B, a system 150 comprises a consumer device 155, a headset 160, and an in-line signal processing unit 165. Consumer device 155 can be any electronic game, music, video, or audio device such as, but not limited to, a radio, TV, computer, a set top box, a home theater system, a Zune, an iPod, a Nintendo DS, a Playstation Portable, or a portable DVD player. In a conventional headset-consumer device system, the sound quality is generally limited by the electronics of device 155 and the quality of headphone 160. In system 150, the sound quality can be enhanced by audio processing unit 165, which can be configured to condition and process the audio signal received from consumer device 155. Unit 165 may be, in one embodiment of the present invention, an add-on device to the consumer device 155, or it may be completely integrated within the consumer device 155. Unit 165 may be of any appropriate size, design or physical configuration, and it may be specifically designed to complement the design, size and/or physical configuration of the consumer device 155 and/or headphone 160.

In one embodiment, unit 165 may condition the received audio signal by adjusting the overall loudness of the signal. Alternatively, unit 165 can adjust the operation setting of various electronic components such as filters and gain controller based on a characteristic such as, but not limited to loudness of the audio signal. The operation setting can be a threshold setting of the filter or the gain controller. Once the audio signal is conditioned or one or more electronic components are re-adjusted, unit 165 can process the audio signal to enhance overall audio quality of headset 160 to near studio quality.

In one embodiment, audio processing unit 165 may be preloaded with various equalizer settings for a variety of sneaker and headset types. F or example, unit 165 may have a preloaded equalizer setting for various audio play back devices such as, but no limited to, built-in speakers of a flat panel television, speaker systems of various manufacturers, and headset by model and manufacturers, etc. Unit 165 may also include a user interface that enables the user to select the appropriate audio play back device. In this way, unit 165 can set the equalizer settings specific to the selected play back device.

FIG. 1C shows an exemplary system 170 where the signal processing method and apparatus can be implemented according to one embodiment of the present invention. Referring now to FIG. 1C, system 150 may comprise media devices 175, in-line audio processing unit 180, speakers 185, and display device 190. Media devices 175 can be a game console 175A, a media player (e.g., DVD, VHS, HD-DVD, Blu-Ray player), and a cable or satellite box 175C. The media can be streamed or stored on any of these devices and can playback to speakers 185 and display 190. Conventionally, audio signals from media device 175 are directly inputted into speaker 185 or display 190, yet the sound quality may be dependent upon the quality of speaker 185 and the built-in speakers of display 190. In contrast, enhanced quality sound and for instance near studio-quality sound can be achieved by coupling audio processing unit 180 in-line with the audio source and the speakers 185 or display 190.

In-line processing unit 180 may be similar to processing unit 165 ad may include one or more features of unit 165. In one embodiment, processing unit 180 may be generally designed for home use; hence, unit 180 may contain various input/output interfaces such as, but not limited to, standard stereo input, optics, and HDMI. Media device 175 can be connected to unit 180 via any of these audio interfaces. In a specific embodiment, media device 175 may be connected to unit 180 via a HDMI connection. In this embodiment, unit 180 can be configured to extract the audio signal from the HDMI input. The extracted audio signal can then be processed using various processing methods described below. Unit 180 can also be connected to display 190 via the same connection type connected at the input (i.e., the HDMI in put from media 175). Alternatively, the connection from unit 180 to speaker 185 and display 190 can be different (e.g., a standard speaker wire is used).

From time-to-time, the present invention is described herein in terms of these example environments. Description in terms of these environments is provided to allow the various features and embodiments of the invention to be portrayed in the context of an exemplary application. After reading this description, it will become apparent to one of ordinary skill in the art how the invention can be implemented in different and alternative environments.

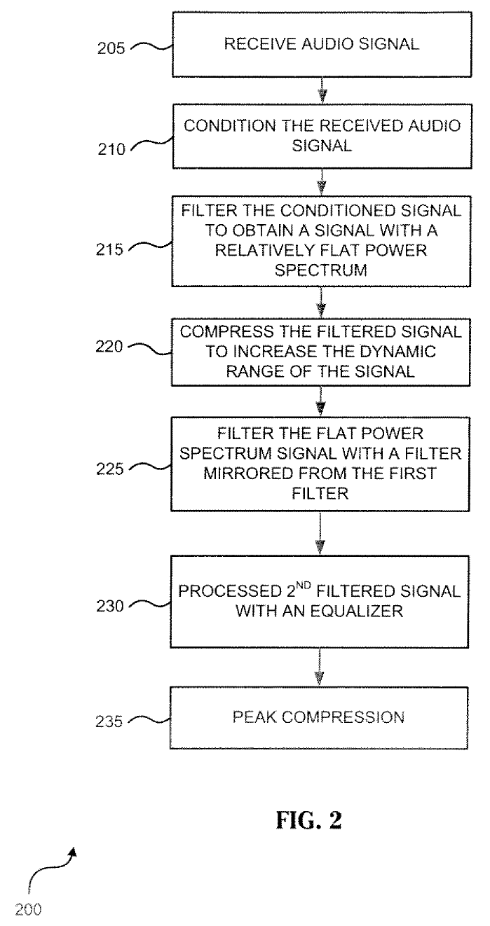

FIG. 2 illustrates a process flow of an audio processing method 200 according to one embodiment of the present invention. In one embodiment, audio processing method 200 may be executable on a computer chip, such as, without limitation, a digital signal processor (“DSP”). The DSP may comprise one or more software and hardware modules working alone or in combination to execute method 200. In one embodiment, such a chip may be one part of a larger device, such as, without limitation, a radio. MP3 player, game station, cell phone, television, computer, or unit 165/180. Referring now to FIG. 2 in a specific embodiment, method 200 starts at step 205 where an audio signal is received from a device such as device 155 or from an audio system of vehicle 105.

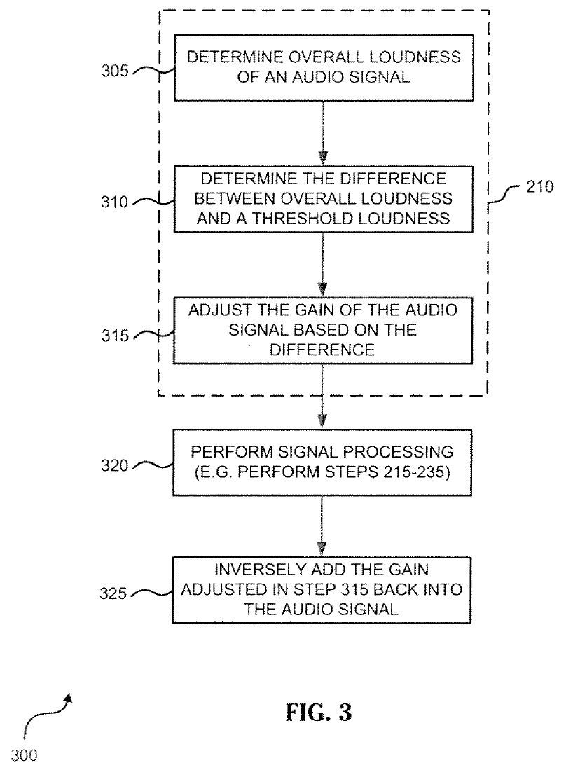

In step 210, the received audio signal can be conditioned prior to the main processing portion of method 200. In one embodiment, the received signal may be filtered to limit low frequencies that can be found in the audio signal. The received signal can also be gain adjusted to modify the gain level of the audio signal. This procedure may include a loudness adjusting step to compensate for loudness variations caused, for example, by the volume control of the output device. In this way, the conditioned signal have a constant loudness and/or gain level before the main processing portion of method 200 begins. Step 210 may include one or more of the above filtering, gain and loudness adjusting steps discussed above. Additionally, the loudness adjusting step will be discussed in further detail in FIG. 3.

In one embodiment, the received signal may be filtered using a pre-input high pass filter. The cut off point of the pre-input high pass filter can be adjusted and in one embodiment, adjusted from about 20 to about 200 Hz. In one embodiment, the pre-input filter has a roll off (slope of gain over frequency curve) and specifically may have a roll-of about 20 dB per octave or more. In another embodiment, the pre-input filter has a roil off of about 20 dB per octave, or less.

In one embodiment, the received signal may be gain adjusted by computing the loudness level of the received signal using a leaky integrator, which generally calculates a slow-moving envelope based on an integrated version of the rectified signal. Once the overall loudness is determined, the received signal can be gain boosted or reduced, for example using an expander or limiter based on, respectively, a threshold or reference loudness. In this embodiment, the signal outputted at this stage can have a relatively constant loudness with respect to a reference or threshold level regardless of the loudness of the source (e.g., regardless of the volume of the audio source). In one embodiment of the present invention, step 210 is optional.

In step 215, the received signal or the conditioned signal from step 210 may be filtered to obtain a signal having in one embodiment, a generally flat power spectral density, i.e., the power or energy distribution across all frequencies is equal. Prior to step 215, the energy spectral density of a signal from an audio source may not be equally distributed in all frequencies. The energy spectral density of the raw audio signal from step 205 is not generally flat, instead, it increases or decreases according to the frequency range of the audio signal.

In one embodiment, step 215 flattens the power spectral density of the audio signal received from step 205 by, in one embodiment, using a high and low shelving filter set combination. Each of the filters can boost or reduce the signal up to about 12 dB, or less. In one embodiment, the crossover point between the high and low frequency filters is located at about 1000 Hz. In one embodiment, the low shelving filter, leaves all of the frequencies above the corner frequency unaltered, while boosting or cutting all frequencies below the corner frequency by a fixed amount (e.g., x dB). In one embodiment, the response of the low shelving filter in cut mode is at −3 dB at the corner frequency, whereas a low-shelving filter in boost mode is specified such that the response at the corner frequency is at G −3 dB—namely, 3 dB down from maximum boost. In step 215 the low shelving filter can be implemented using a weighted sum of high-pass and low-pass filters.

In general, the raw audio signal received from step 205 can contain a pink noise portion and a white noise portion. The pink noise portion generally can span the entire frequency spectrum of the raw audio signal. Pink noise has equal energy in each octave. The white noise portion may also span the entire frequency spectrum of the raw audio signal, however, white noise contains equal energy at all frequencies. For pink noise, lower frequencies contain more energy than in higher frequencies.

In one embodiment, the low and high shelving filters may be configured to flatten the energy spectral density from the pink and white noise portion of the raw audio signal. In one embodiment, the filters may be configured to remove more energy from lower frequencies of the raw audio signal. Typically, more energy is stored in the lower frequencies of the pink noise portion of an audio signal. In a specific embodiment, in step 210, the low audible bass portion of the raw audio signal (taken at 100 Hz) may be reduced by about 10 dB. Similarly, the high audible treble portion (taken at 8 kHz) may be increased by about 8 dB, and the portions in between, in one embodiment, may be reduced or enhanced in a linearly proportional manner, i.e., the increase is a substantially linear function of frequency. In this way, the high-low shelving filter set produces a generally flat energy spectral density across a wide range of frequencies (e.g., low audible bass to high audible treble frequencies).

In step 220, the filtered signal may be compressed to increase the dynamic range of the received audio signal using a gain controller or compressor. In one embodiment, the gain controller may be configured to alter the dynamic range of a signal by reducing the ratio of the signal's peak level to its average level. A gain controller is characterized by four quantities: the attack time, Tₐₜₜ, the release time, Tᵣₑₗ, the threshold, KT, and the ratio, r. In brief the envelope of the signal is tracked by an algorithm that gives a rough “outline” of the signal's level. Once that level surpasses the threshold, KT, for a period of time equal to Tₐₜₜ, the gain controller decreases the level of the signal by the ratio r dB for every dB above KT. Once the envelope of the signal falls below KT for a period equal to the release time, Tᵣₑₗ, the gain controller stops decreasing the level.

In step 225, the compressed signal from step 220 can be further filtered in order to convert the signal having a flat energy spectral density to a signal having a full frequency response (i.e., energy spectral density is no longer flat). On a high level, the signal with a flat energy spectral density may be reconstructed into a signal with a flat frequency response and having a variable energy spectral density. In one embodiment this can be accomplished using a set of low-high shelving filter that is a mirror image of the low-high shelving filter set in step 215. In one embodiment, all frequencies below the corner frequency are left unmodified, whereas the frequencies above the corner frequency are boosted or cut by ‘x’ dB. Similar to the first low-high shelving filter set in step 215, the second low-high filter set has a crossover point at 1000 Hz. Each of the filters can boost or reduce the signal level by 12 dB.

In step 230, the reconstructed signal from step 225 is further processed by an equalizer. The operational settings of the equalizer can be manually set by an audio engineer. The equalizer allows an audio engineer to finely tune and enhance the output signal based on various factors such as, but not limited to, the physical limitation of the speakers and the environment. In one embodiment, the equalizer is a 10 band fully parametric equalizer. The equalizer may have a number of second order filters and in a specific embodiment, it may comprise eleven cascading second order filters. In one embodiment, each of the filters in the equalizer can boost or reduce the signal level by 18 dB or −12 dB, respectively. In one specific embodiment, the quality factor of the band can be individually adjusted from about 0.4 to about 8.0.

In another specific embodiment, each cascading second order filter may be a bell filter. The eleven second order filters may achieve a bell-shaped boost or cut at a fixed center frequency, with the first filter centered, for example, at 30 Hz and the eleventh filter centered, for example, at 16000 Hz. All of the other filters in between the first and the eleventh filters, in one embodiment, may be centered at roughly one-octave intervals.

As mentioned, audio processing unit 170 may be preloaded with various equalizer settings for a variety of speaker and headset types. Unit 170 may also include a user interface that enables the user to select the appropriate audio play back device. For example, the user may enter a specific code for a particular headset to calibrate the equalizer of unit 170 for optimum near-studio audio quality output. The code can be included along with the operational manual of unit 170 or can be located, for example, via the manufacturer of unit 170 website.

In step 235, the output signal from step 230 may be further compressed. In one embodiment, a split band compressor may be used. In a specific embodiment, the split band compressor may comprise a low frequency compressor that operates in the range of about 0 to about 500 Hz and a high frequency compressor that operates in the range of about 10 k to about 20 k Hz. In one specific exemplary embodiment, each compressor may have the following specifications: threshold of 0 to −52 dB, ratio of 1:1 to 800:1; make up gain of +12 dB to 90 dB; attack time of 0 to 99 ms, and release time of 0 to 495 ms. In one embodiment one of the main functions of step 235 is to allow the speaker or headset to operate in a range that is near its physical design limitations. Although not shown, in one embodiment, the output signal from step 235 can be further gain adjusted to compensate for any loudness/gain adjustment that was done in step 210.

FIG. 3 illustrates a detailed process flow of a portion of step 210 according to one embodiment of the present invention. Referring now to FIG. 3, a method 300 for adjusting the loudness of an audio signal is shown. Method 300 may be typically used in a system where the loudness of the audio source can be varied by a volume adjustment, such as an audio output from a portable music or video player or a portable gaming device. In one embodiment, audio processing unit 165 (shown in FIG. 1) may be configured to work with an audio source having a prescribed gain or loudness value when performing steps 215-235 as described in FIG. 2. Thus, when the volume is substantially lowered or raised, downstream signal processing performed by unit 165 may be distorted because the loudness is not at the expected level. Thus, method 300, in one embodiment, can be used to generate an output signal with a predetermined loudness regardless of the volume of the input audio signal. In this way, unit 165 may perform steps 215-235 as designed and without added distortion.

In step 305, the overall loudness of the received signal from step 205 is determined. As mentioned, this may be done, in one embodiment, with a leaky integrator. Other methods to determine loudness can also be used.

In step 310, the determined loudness may be compared with a threshold loudness, which may be manually set. The threshold loudness may be typically based on the filters and the gain stages inside of audio processing unit 165.

In step 315, the gain of the raw audio signal may be adjusted based on the comparison done in step 310. In one embodiment, if the loudness is above the threshold, the gain of the audio signal is reduced. In one embodiment, the gain of the audio signal may be reduced using a limiter. Other gain reduction methods can also be used. In one embodiment, if the loudness is below the threshold, the gain of the audio signal is increased. In one embodiment, the gain may be increased with an expander. Other gain boosting methods can also be used in the context of the present invention.

After the gain is adjusted in step 315, the signal can be further processed in step 320. For example, in a specific embodiment, the signal can be further processed using steps 215 to 235 of method 200. In a step 325, the gain added to or subtracted from the audio signal in step 315 may be subtracted or added back in by an amount that is approximately or exactly inverse to the amount taken or added in step 315. In this way, the original vole control may be mimicked at the end of method 300.

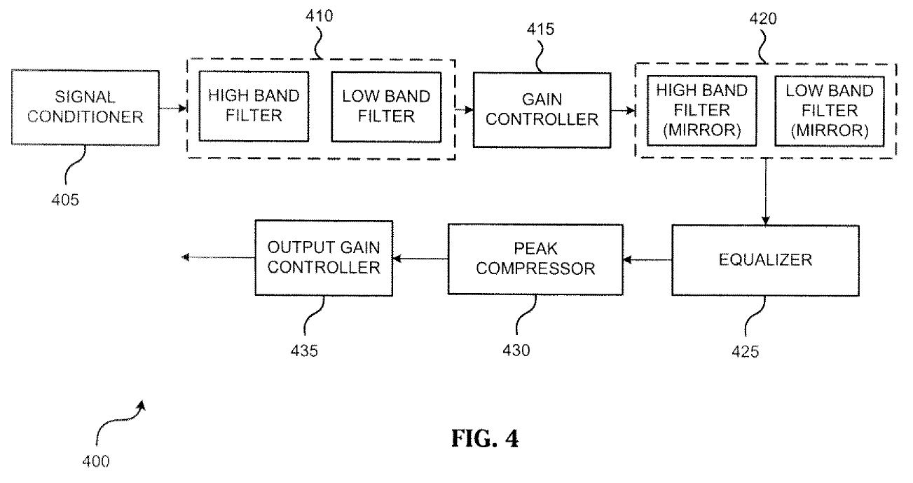

FIG. 4 illustrates an example digital signal process flow of a method 400 according to one embodiment of the present invention. Referring now to FIG. 4, method 400 comprises, in a specific embodiment, the following stages: a signal conditioning stage 405 first low-high shelve filtering stage 410) a first compressor stage 415, a second low-high shelve filtering stage 420, an equalizer 425) a second compressor stage 430, and an output gain adjustment stage 435.

Similar to method 200, methods 300 and 400 may be executable on a computer chip, such as, without limitation, a digital signal processor, or DSP. In one embodiment, such a chip may be one part of a larger audio device, such as, without limitation, a radio, MP3 player) game station, cell phone, television, computer, or public address system. In one such embodiment, digital signal processing method 100 may be performed on the audio signal before it is outputted from the audio device. In one such embodiment, digital signal processing method 400 may be performed on the audio signal after it has passed through the source selector, but before it passes through the volume control.

In one embodiment, conditioner stage 405 provides a desired amount of gain in order to bring the input audio signal to step 410 to a level that will prevent digital overflow at subsequent internal points in digital signal processing method 100.

In one embodiment, each of the low-shelf filters in filter stages 410 and 420 may be a filter that has a nominal gain of in a specific embodiment, about 0 dB for all frequencies above a certain frequency termed the corner frequency. For frequencies below the corner frequency, the low-shelving filter, in a specific embodiment, has a gain of ±G dB, depending on whether the low-shelving filter is in boost or cut mode, respectively.

In FIG. 4, the compressed audio signal from stage 415 may be applied to the input of gain controller stage 420. Gain controller stage 420 provides a degree of amplification which is inversely related to signal amplitude. Low amplitude portions of the signal are provided with higher gain amplification than high amplitude portions with the result that the dynamic range of represented sounds is lowered (Quiet Sounds would be raised; loud sounds would be lowered). Preferably the dynamic range is reduced to about 10 dB or less. A variety of compressor circuits are known and can be utilized in this context.

After compression of the electrical audio signal at stage 415, the signal received at stage 420 may be subjected to “mirror image” equalization in mirror image filtering stage 420. At this stage, the bass portion of the signal is increased while the treble portion is reduced. The low audible bass portion (100 Hz) may be increased up to 12 dB and high audible treble portion (10 kHz) may be reduced by up to 12 dB. In one specific embodiment, the low audible bass portion (100 Hz) may be increased about 10 dB and high audible treble portion (10 kHz) may be reduced by about 8 dB. The intermediate portions of the signal may be reduced as a substantially linear function of frequency. In a specific embodiment, the equalizer 415 and the “mirror image” equalizer or gain controller 415 are chosen so that they have equal and opposite effects.

After equalization, compression and mirror image equalization, the processed audio signal may be applied to speaker system or headset 160, either directly or, in a specific embodiment, through a multiple-band equalizer (not shown in FIG. 1) for sound presentation. The speaker system, in one embodiment, may comprise small speakers (having magnets smaller than about 10 oz), for presentation of sound in a high-noise environment. Because the bass portion was reduced before compression and enhanced after compression, the sound presented by the speakers has a spectrum rich in bass tones and free of the muffling effect encountered in conventional compression. And because the dynamic range is reduced by compression, the sound can be presented within the limited volume range between the about 80 dB noise floor and the about 110 dB threshold of unpleasant sensation.

Also shown as parts of the preferred circuit are an optional power supply 20 and a 10-band graphic equalizer 21 for a specific speaker assembly. The equalizer 21 may be disposed at the output of mirror image equalizer 13.

In one embodiment, the signal processor described herein may be designed to accommodate the conversion of music composition and movie sound tracks with wide dynamic ranges to a very narrow dynamic range without distorting or altering the original work. It may be particularly suited for playing music or movies in high ambient noise environments such as aircraft or boats. Additional applications include the home, shopping malls, performance theaters, automobiles, bars and clubs as well as high noise environments where music or sound needs to be reproduced; e.g., amusement parks, clubs and racetracks.

By using equalization and compression in this fashion, the control of the frequency response of the program materials can be altered to such a degree that it can cause a transducer to pass the sound through and within conventional vehicle and in one embodiment boat and aircraft interiors without exposing the transducer to the acoustic environment.

Unless defined otherwise, all technical and scientific terms used herein have the same meaning as is commonly understood by one of ordinary skill in the art to which this invention belongs. All patents, applications, published applications and other publications referred to herein are incorporated by reference in their entirety. If a definition set forth in this section is contrary to or otherwise inconsistent with a definition set forth in applications, published applications and other publications that are herein incorporated by reference, the definition set forth in this section prevails over the definition that is incorporated herein by reference.

The term “tool” can be used to refer to any apparatus configured to perform a recited function. For example, tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance on which software runs or in which hardware is implemented.

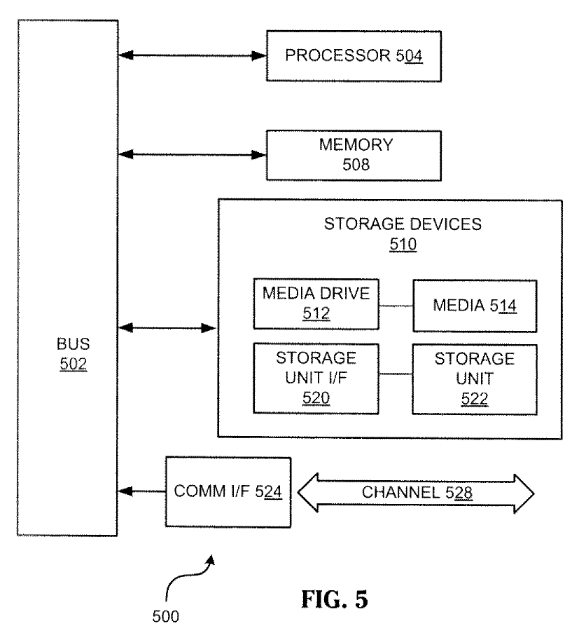

As used herein, the term “module” might describe a given unit of functionality that can be performed in accordance with one or more embodiments of the present invention As used herein, a module might be implemented utilizing any form of hardware, software, or a combination thereof. For example, one or more processors, controllers. ASICs. PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the an various features and functionality described herein may be implemented in any given application and can be implemented in one or more separate or shared modules in various combinations and permutations. Even though various features or elements of functionality may be individually described or embodied as separate modules, one of ordinary skill in the art will understand that these features and functionality can be shared among one or more common software and hardware elements, and such description shall not require or imply that separate hardware or software components are used to implement such features or functionality.

Where components or modules of the invention are implemented in whole or in part using software, in one embodiment, these software elements can be implemented to operate with a computing or processing module capable of carrying out the functionality described with respect thereto. One such example-computing module is shown in FIG. 5. Various embodiments are described in terms of this example-computing module 500. After reading this description, it will become apparent to a person skilled in the relevant art how to implement the invention using other computing modules or architectures.

Referring now to FIG. 5, computing module 500 may represent, for example, computing or processing capabilities found within desktop, laptop and notebook computers; hand-held computing devices (PDA's, smart phones, cell phones, palmtops, etc.); mainframes, supercomputers, workstations or servers; or any other type of special-purpose or general-purpose computing devices as may be desirable or appropriate for a given application or environment. Computing module 500 might also represent computing capabilities embedded within or otherwise available to a given device. For example, a computing module might be found in other electronic devices such as, for example, digital cameras, navigation systems, cellular telephones, portable computing devices, modems, routers, WAPs, and other electronic devices that might include some to of processing capability.

Computing module 500 may include, for example, one or more processors or processing devices, such as a processor 504. Processor 504 may be implemented using a general-purpose or special-purpose processing engine such as, for example, a microprocessor, controller, or other control logic. In the example illustrated in FIG. 5, processor 504 may be connected to a bus 502 or other communication medium to facilitate interact on with other components of computing module 500.

Computing module 500 may also include one or more memory modules, referred to as main memory 508. For example, preferably random access memory (RAM) or other dynamic memory, may be used for storing information and instructions to be executed by processor 504. Main memory 508 may also be used for storing temporary variables or other intermediate information during execution of instructions to be executed by processor 504. Computing module 500 may likewise include a read only memory (ROM) or other static storage device coupled to bus 502 for storing static information and instructions for processor 504.

The computing module 500 may also include one or more various forms of information storage mechanism 510, which may include, for example, a media drive 512 and a storage unit interface 520. The media drive 512 may include a drive or other mechanism to support fixed or removable storage media 514. For example, a hard disk drive, a floppy disk drive, a magnetic tape drive, an optical disk drive, a CD or DVD drive (R or RW), or other removable or fixed media drive. Accordingly, storage media 514, may include, for example, a hard disk, a floppy disk, magnetic tape, cartridge, optical disk, a CD or DVD, or other fixed or removable medium that is read by, written to or accessed by media drive 512. As these examples illustrate, the storage media 514 may include a computer usable storage medium having stored therein particular computer software or data.

In alternative embodiments, information storage mechanism 510 may include other similar instrumentalities for allowing computer programs or other instructions or data to be loaded into computing module 500. Such instrumentalities may include, for example, a fixed or removable storage unit 522 and an interface 520. Examples of such storage units 522 and interfaces 520 may include a program cartridge and cartridge interface, a removable memory (for example, a flash memory or other removable memory module) and memory slot, a PCMCIA slot and card, and other fixed or removable storage units 522 and interfaces 520 that allow software and data to be transferred from the storage unit 522 to computing, module 500.

Computing module 500 may also include a communications interface 524. Communications interface 524 may be used to allow software and data to be transferred between computing module 500 and external devices. Examples of communications interface 524 might include a modem or softmodem, a network interface (such as an Ethernet, network interface card, WiiMedia, 802.XX or other interface), a communications port (such as for example, a USB port, IR port, RS232 port Bluetooth interface, or other port), or other communications interface. Software and data transferred via communications interface 524 may be carried on signals, which can be electronic, electromagnetic, optical or other signals capable of being exchanged by a given communications interface 524. These signals may be provided to communications interface 524 via a channel 538. This channel 528 may carry signals and may be implemented using a wired or wireless medium. Some examples of a channel may include a phone line, a cellular link, an RF link, an optical link, a network interface, a local or wide area network, and other wired or wireless communications channels.

In this document, the terms “computer program medium” and “computer usable medium” are used to generally refer to media such as, for example, memory 508, storage unit 520, media 514, and signals on channel 528. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing module 500 to perform features or functions of the present invention as discussed herein.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of ordinary skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method embodiments, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof unless otherwise expressly stated, should be construed as open ended as opposed to limiting. As examples of the foregoing, the term “including” should be read as meaning “including,” “without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read as to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise Similarly, a group of items linked with the conjunction “or” should not be read as requiring mutual exclusivity among that group, but rather should also be read as “and/or” unless expressly stated otherwise. Furthermore, although items, elements or components of the invention may be described or embodied in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or embodied as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. A method comprising the steps of:
receiving an audio signal;
filtering the audio signal to obtain a generally flat power spectral density across a plurality of frequencies of the audio signal;
compressing the filtered audio signal to increase a dynamic range of the filtered audio signal;
filtering the compressed audio signal to generate an audio signal with a variable energy spectral density; and
outputting the audio signal.

2. The method of claim 1, wherein the filtering comprises filtering the audio signal with a high shelving filter and a low shelving filter.

3. The method of claim 2, wherein each filter has a cutoff frequency of approximately 1000 Hz.

4. The method of claim 1, wherein the filtering reduces a power of a low audible bass portion of the audio signal by approximately 10 dB.

5. The method of claim 1, wherein the filtering reduces a power of a high audible treble portion of the audio signal by approximately 8 dB.

6. The method of claim 1, further comprising conditioning the filtered audio signal having the variable energy spectral density with an equalizer.

7. The method of claim 6, wherein the graphic equalizer comprises eleven cascading second order filters, each filter comprises a bell filter.

8. The method of claim 7, wherein the first of the eleven filters has a center frequency, of 30 Hz and the eleventh filter of the eleven filters has a center frequency of 16000 Hz.

9. The method of claim 6, wherein the second to tenth filters are centered at approximately one octave intervals from each other.

10. The method of claim 6, further comprising compressing the conditioned audio signal with a second compressor.

11. The method of claim 10, further comprising amplifying a gain of the compressed signal prior to outputting the signal.

12. An audio processing apparatus comprising:
a first set of filters configured to filter an audio signal to obtain a generally flat power spectral density across a plurality of frequencies of the audio signal;
a gain controller configured to increase a dynamic range of the filtered audio signal; and
a second set of filters configured to generate an audio signal with a variable energy spectral density.

13. The audio processing apparatus of claim 12, wherein the first set of filters comprises a high shelving filter and a low shelving filter.

14. The audio processing apparatus of claim 13, wherein each filter has a cutoff frequency of approximately 1000 Hz.

15. The audio processing apparatus of claim 12, wherein the first set of filters reduces a power of a low audible bass portion of the audio signal by approximately 10 dB.

16. The audio processing apparatus of claim 12, wherein the first set of filters reduces a power of a high audible treble portion of the audio signal by approximately 8 dB.

17. The audio processing apparatus of claim 12, further comprising an equalizer for conditioning the audio signal from the second set of filters.

18. The audio processing apparatus of claim 17, wherein the graphic equalizer comprises eleven cascading second order filters, wherein each filter comprises a bell filter.

19. The audio processing apparatus of claim 18, wherein the first of the eleven filters has a center frequency of 30 Hz and the eleventh filter of the eleven filters has a center frequency of 16000 Hz.

20. The audio processing apparatus of claim 18, wherein the second to tenth filters are centered at approximately one octave intervals fom each other.

21. The audio processing apparatus of claim 17, further comprising a compressor configured to compress the conditioned audio signal.

22. The audio processing apparatus of claim 21, further comprising an amplifier configured to amplify a gain of the compressed signal prior to outputting the signal.
